(19) United States
(12) Patent Application Publication
(10) Pub. No.: US 2026/0221379 A1
(43) Pub. Date: Jul. 30, 2026

(54) CHARGED PARTICLE BEAM DEVICE, IMAGE PROCESSING METHOD, AND IMAGE PROCESSING PROGRAM

(71) Applicant: Hitachi High-Tech Corporation, Tokyo (JP)

(72) Inventors: Shunya TANAKA, Tokyo (JP); Hirokazu TAMAKI, Tokyo (JP); Yoshinobu HOSHINO, Tokyo (JP); Hiromi MISE, Tokyo (JP); Takashi SHIDARA, Tokyo (JP)

(73) Assignee: Hitachi High-Tech Corporation, Tokyo (JP)

(21) Appl. No.: 19/145,423

(22) PCT Filed: Jan. 26, 2023
(86) PCT No.: PCT/JP2023/002346

§ 371 Date: Jul. 2, 2025

(51) Int. Cl. H01J 37/22; G01N 23/04; H01J 37/28

(52) U.S. Cl. CPC H01J 37/222; G01N 23/04; H01J 37/28; G01N 2223/102; G01N 2223/401; G01N 2223/408; H01J 2237/225

(57) ABSTRACT

Provided is a charged particle beam device comprising: an image forming unit that forms a frame image, the frame image being a charged particle beam image based on a detection signal from a detector; and an image processing unit that performs image processing on the frame image, in which: the image forming unit acquires a plurality of frame images in an integration direction; and the image processing unit, for each pixel that constitutes the frame image, performs fitting using a model in which a change in an image brightness value of the pixel is designated, to obtain a brightness value change curve, and generates a fitted image in which the brightness values of the pixels are based on the brightness value change curve.

### TECHNICAL FIELD

The present invention relates to a charged particle beam device, an image processing method, and an image processing program.

### BACKGROUND ART

A scanning electron microscope (SEM) capable of easily observing various samples on the order of nanometer is an essential tool in development sites in various fields such as semiconductor, material, and biotechnology. However, since the SEM irradiates a sample with an electron beam to form an image, for example, in a sample containing an organic material or the like and having a fine structure, the influence of sample damage caused by the electron beam irradiation is remarkable. Low-dose observation such as observation under a low acceleration voltage is known as a method for avoiding the sample damage caused by the electron beam irradiation. In the low-dose observation, it is possible to reduce sample damage (for example, sample deformation and contrast change) caused by the observation by reducing an amount of electrons radiated onto the sample. On the other hand, in the low-dose observation, since an amount of generated secondary electrons is also reduced, an SEM image having a low signal to noise ratio (SNR) and roughness is obtained. Therefore, in the low-dose observation, image processing is generally performed in which an SEM image with a low SNR is repeatedly acquired in a range without sample damage, and the obtained SEM images are integrated to increase the SNR. However, when a speed at which a sample is damaged by the electron beam irradiation is high, a sufficient number of SEM images cannot be integrated, and thus it is difficult to obtain an SEM image with a high SNR while preventing damage to the sample. In this manner, there is a trade-off relationship between obtaining an SEM image while preventing sample damage and obtaining an SEM image with a high SNR.

For example, PTL 1 discloses a method for obtaining an SEM image with a high SNR while preventing sample damage. In PTL 1, images of repetitive patterns having the same or similar shapes formed on a sample are acquired by moving the field of view, and acquired signals are integrated to form an SEM image (or signal waveform) with a high SNR.

It is also generally known to apply an image processing method to increase an SNR of an SEM image. A high SNR can be achieved by performing image processing for removing noises on an SEM image having a low SNR. For example, a method for removing noises by referring to brightness value information of peripheral pixels as in median blur processing or a method for removing noises by removing a frequency component corresponding to noises as in low-pass filter processing may be applied. In addition, the application of a method for removing noises by performing machine learning using, as teacher images, an SEM image with a high SNR and an image with a low SNR generated by adding noises to the SEM image with a high SNR is conceivable.

### CITATION LIST

### Patent Literature

PTL 1: WO2011/030508

### SUMMARY OF INVENTION

### Technical Problem

The method disclosed in PTL 1 is based on a premise that a plurality of observation targets having the same or similar shapes are present in a sample. However, a sample in which a plurality of observation targets having the same or similar shapes are present in the sample is limited, and it is difficult to obtain a sufficient number of integration images for a sample that does not have a periodic pattern structure.

An image processing method needs to be a method capable of increasing an SNR of an SEM image with a low SNR without being restricted by such a sample structure. However, an SEM image obtained by low-dose observation often has a very low SNR, and a sufficiently high SNR cannot be obtained by general noise removal processing in many cases. In the method using machine learning, a fine structure that should not be seen may appear due to the teacher images, and there is a problem that appropriateness and the sense of satisfaction of an image after noise removal processing are low.

The invention has been made in view of these problems, and an object of the invention is to provide a charged particle beam device capable of acquiring a charged particle beam image with a high SNR, an image processing method and an image processing program for improving an SNR of a charged particle beam image with a low SNR.

### Solution to Problem

A charged particle beam device according to an embodiment of the invention includes a charged particle optical system configured to irradiate a sample with a charged particle beam, a detector configured to detect particles or electromagnetic waves generated by irradiating the sample with the charged particle beam, an image forming unit configured to form a frame image that is a charged particle beam image based on a detection signal from the detector, and an image processing unit configured to perform image processing on the frame image, in which the image forming unit acquires a plurality of the frame images in an integration direction, and the image processing unit obtains a brightness value change curve by using a designated model to fit a change of an image brightness value of a pixel in the integration direction for each pixel constituting the frame image, and generates a fitted image in which a brightness value of the pixel is a value based on the brightness value change curve.

### Advantageous Effects of Invention

A technique capable of acquiring a charged particle beam image with a high SNR is provided. Other technical problems and novel features will become apparent from description of the present description and the accompanying drawings.

### BRIEF DESCRIPTION OF DRAWINGS

FIG. 1A is a schematic configuration diagram illustrating a charged particle beam device.

FIG. 1B is a schematic configuration diagram illustrating a computer.

FIG. 2 is a diagram illustrating a configuration of a GUI.

FIG. 3 is a flowchart illustrating high-SNR imaging.

FIG. 4 is a flowchart illustrating calculation of a brightness value change curve.

FIG. 5 is a display example of the GUI immediately after a frame image is acquired.

FIG. 6 is a diagram illustrating a brightness value change curve calculation method and a fitted image generation method.

FIG. 7 is a display example of the GUI after a fitted image is generated.

FIG. 8 is a display example of the GUI after an SNR increasing parameter is updated.

FIG. 9 is a diagram illustrating a configuration of a GUI.

FIG. 10 is a display example of the GUI immediately after a frame image is acquired.

FIG. 11 is a display example of the GUI after a fitted image is generated.

FIG. 12 is a display example of the GUI after an SNR increasing parameter is updated.

FIG. 13 is a display example of the GUI for acquiring an image with a high SNR under a desired observation condition.

FIG. 14 is a display example of the GUI after a fitted image is generated.

FIG. 15 is a diagram illustrating a method for classifying regions in an image.

### DESCRIPTION OF EMBODIMENTS

### Embodiment 1

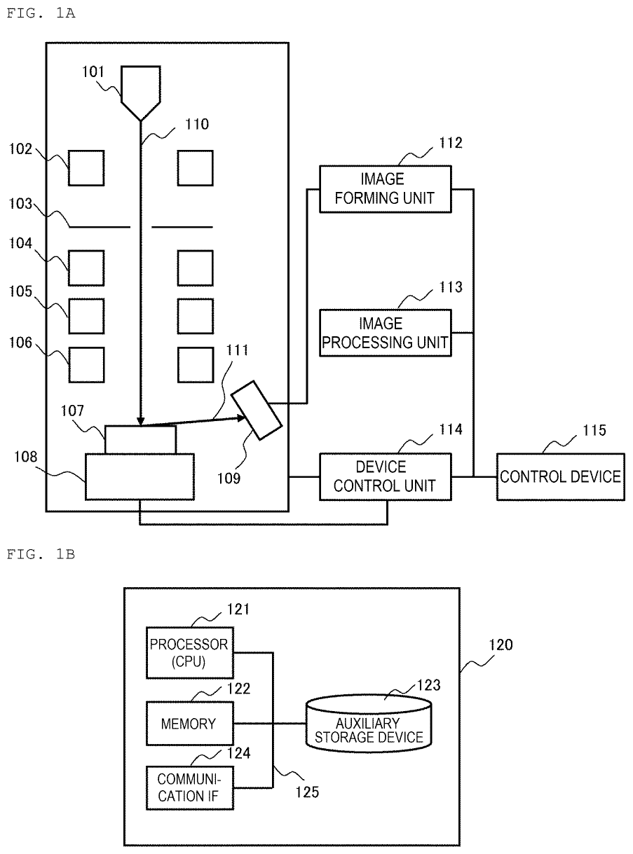

FIG. 1A illustrates a schematic configuration of a charged particle beam device. Hereinafter, an SEM will be described as an example of the charged particle beam device, but the charged particle beam device is not limited thereto. For example, the charged particle beam device may be a transmission electron microscope (TEM), a scanning transmission electron microscope (STEM), and an ion microscope.

The charged particle beam device includes, as main components, an electron optical system including an electron gun 101, a condenser lens 102, a diaphragm 103, a deflection coil 104, a stigma coil 105, and an objective lens 106, a sample stage 108 on which a sample is placed, and a detector 109. The electron gun 101 emits an electron beam 110, the condenser lens 102 and the objective lens 106 finely condense the electron beam 110, the diaphragm 103 adjusts an aperture angle of the electron beam 110, the deflection coil 104 deflects scanning and an irradiation direction of the electron beam 110, and the stigma coil 105 corrects astigmatism of the electron beam 110. The detector 109 detects secondary electrons 111 generated when a sample 107 is irradiated with the electron beam 110.

Although an example in which electrons are used as charged particles radiated onto a sample has been described here, a charged particle beam such as an ion beam may be used instead of the electron beam 110. Further, particles detected by the detector 109 are not limited to the secondary electrons 111, but may be particles such as ions secondarily generated by irradiation with a charged particle beam or electromagnetic waves such as X-rays, and in this case, a detector capable of detecting particles or electromagnetic waves to be detected is used as the detector 109.

An image forming unit 112 forms a charged particle beam image based on a detection signal from the detector 109. The charged particle beam image formed by the image forming unit 112 is referred to as a frame image. The frame image is a raw image on which image processing for increasing a SNR is not performed. The image forming unit 112 transmits the frame image to an image processing unit 113 and a control device 115.

The image processing unit 113 performs image processing on the frame image formed by the image forming unit 112. An image subjected to the image processing by the image processing unit 113 which will be described later is referred to as a fitted image. The image processing unit 113 transmits the fitted image to the control device 115.

A device control unit 114 controls parameters related to the electron optical system, the sample stage 108, and the image forming unit 112 to acquire a frame image. The device control unit 114 can acquire and store the parameters related to the electron optical system, and can transmit the parameters to the image processing unit 113.

The image forming unit 112, the image processing unit 113, and the device control unit 114 are connected to the control device 115. The control device 115 includes an interface for a measurer, and the measurer can input parameters related to high-SNR imaging from an input device provided in the control device 115 and can confirm a frame image, a fitted image, and a fitting result displayed on a display device provided in the control device 115.

The image forming unit 112, the image processing unit 113, and the device control unit 114 are implemented as, for example, a calculation processing board including a microprocessor, and the control device 115 can be implemented as a personal computer (PC). Regardless of an implementation form, these units have a basic configuration as a computer illustrated in FIG. 1B. The computer illustrated in FIG. 1B includes a processor (CPU) 121, a memory 122, an auxiliary storage device 123, a communication interface 124, and a bus 125 as main components. The processor 121 functions as a functional unit that provides a predetermined function by executing processing according to a program loaded in the memory 122. The auxiliary storage device 123 stores a program for causing the processor to function as a functional unit and data used or generated by the functional unit. A volatile memory such as a DRAM is used as the memory 122, and a nonvolatile memory such as a flash memory is used as the auxiliary storage device 123. The communication interface 124 enables communication with other computers. These components are communicably connected to one another via the bus 125.

For example, taking the image processing unit 113 as an example, an image processing program is stored in the auxiliary storage device 123, and the processor 121 loads the image processing program into the memory 122 and performs processing according to the program, which enables the computer 120 to function as the image processing unit 113. The image forming unit 112, the device control unit 114, and the control device 115 are connected via the communication interface 124, and input and output of a frame image, a fitted image, a fitting result, parameters used for image processing, and the like via the communication interface 124. A frame image used for image processing, parameters, and a processing result of a program are stored in the auxiliary storage device 123.

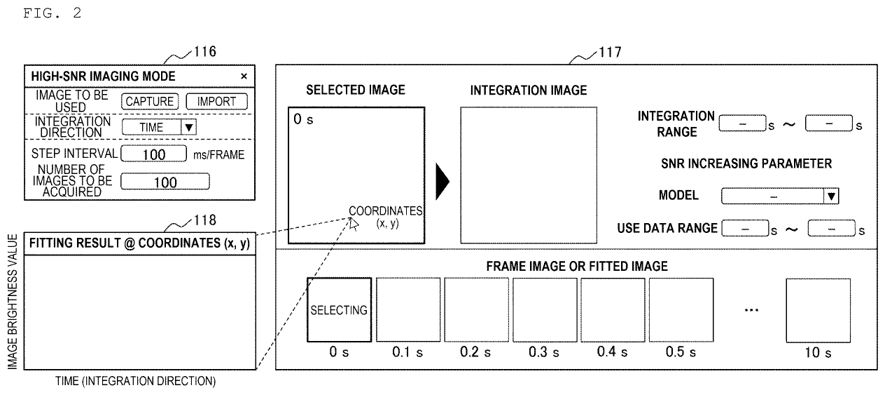

FIG. 2 illustrates a configuration of a graphical user interface (GUI) displayed on a display device provided in the control device 115. The GUI displayed on the display device provided in the control device 115 includes windows 116 to 118. The window 116 is a window for a measurer to input parameters related to high-SNR imaging. The window 117 is a window for inputting parameters necessary for the image processing unit 113 to increase an SNR of a frame image and displaying a frame image or a fitted image. The window 118 is a window for displaying a result of increasing the SNR by the image processing unit 113.

The parameters input to the control device 115 by the measurer according to the GUI are transmitted to the image processing unit 113 or the device control unit 114. A parameter input method may not be based on the GUI, and a text file in which parameters are registered may be read.

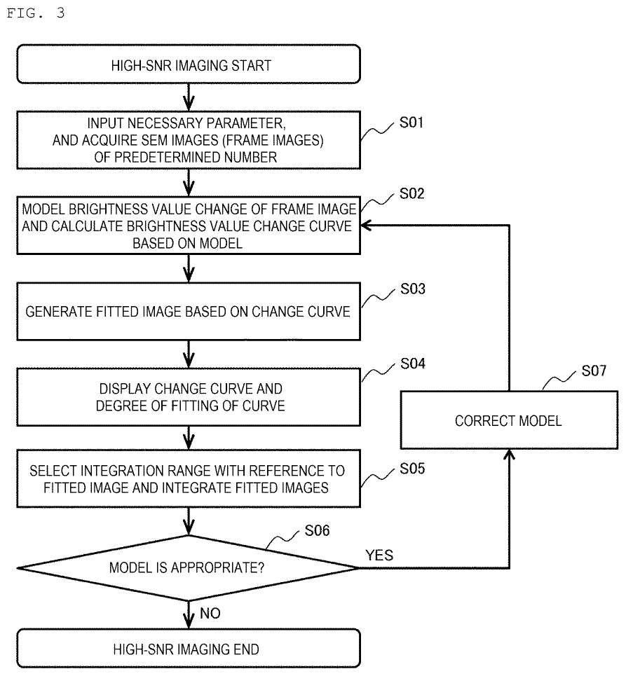

Next, a sample observation method using the charged particle beam device according to the present embodiment will be described. FIG. 3 is a flowchart illustrating high-SNR imaging.

First, a plurality of frame images necessary for high-SNR imaging are acquired (S01). Therefore, a measurer inputs parameters necessary for high-SNR imaging to the window 116 of the GUI (see FIG. 2). In the present embodiment, parameters of “image to be used”, “integration direction”, “step interval”, and “number of images to be acquired” are prepared. In the “image to be used”, the measurer selects whether to capture an image to be used as a frame image in a current field of view of the charged particle beam device or whether to import an image that was saved in the past. In the “integration direction”, the measurer selects to change which one parameter to acquire a series of frame images. In the “step interval”, the measurer designates an interval for acquiring the series of frame images according to the integration direction. In the “number of images to be acquired”, the measurer specifies the number of frame images to be acquired. The control device 115 transmits the input parameters to the device control unit 114, and based on the parameters, the device control unit 114 acquires a frame image formed by the image forming unit 112. In the example illustrated in FIG. 2, since the integration direction is time, a step interval is defined as an interval for acquiring a frame image. When the step interval is 100 ms per frame and the number of images to be acquired is 100, frame images are continuously captured every 100 ms for 10 seconds. The captured frame images are transmitted from the image forming unit 112 to the image processing unit 113 and the control device 115.

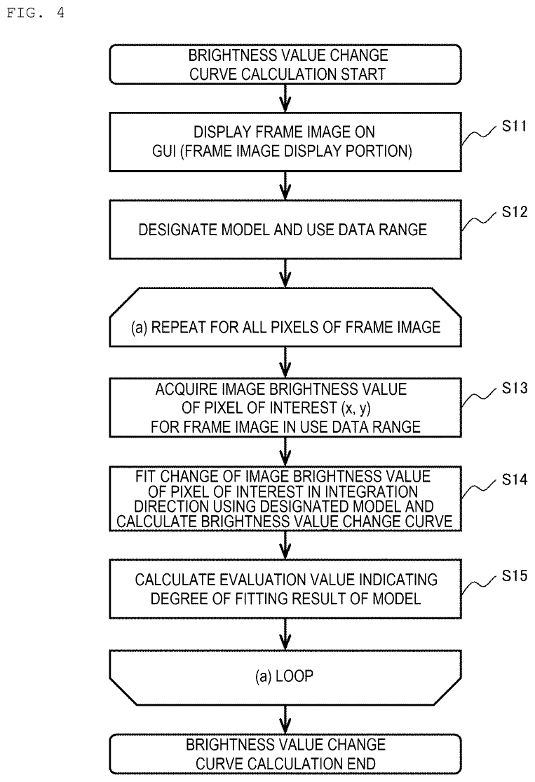

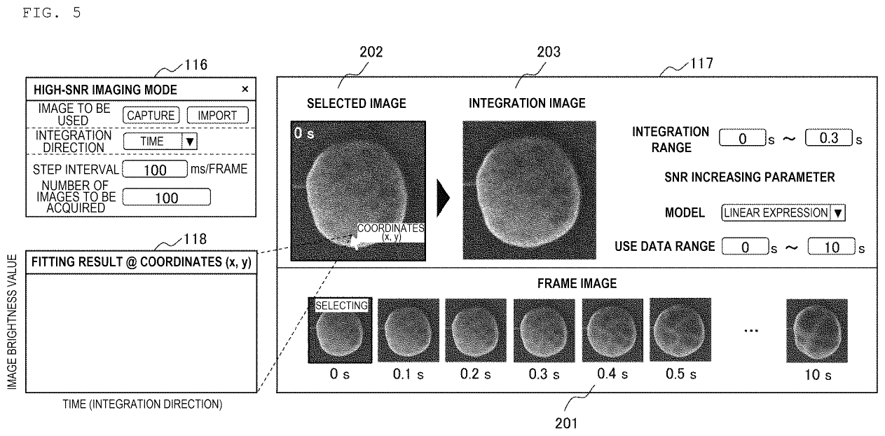

Next, a change in a brightness value of the captured frame image in the integration direction is modeled to calculate a brightness value change curve (S02). FIG. 4 is a flowchart illustrating the calculation of the brightness value change curve, and FIG. 5 illustrates a state of the GUI at this time.

The control device 115 displays the frame images transmitted from the image forming unit 112 on the GUI (S11). As illustrated in FIG. 5, all frame images are displayed in a frame image display region 201 of the window 117 in the integration direction, in this case, in a time direction. A frame image selected by the measurer in the frame image display region 201 is enlarged and displayed in a selected image display region 202. Further, when an integration range is designated, an image obtained by integrating frame images in the designated range (0 s to 0.3 s in the example in FIG. 5) is displayed in an integration image display region 203.

With reference to the frame images displayed on the GUI, the measurer designates a “model” for performing fitting and a “use data range” that is a range of frame images to be used for modeling, as SNR increasing parameters (S12). For modeling, a fitting curve of a polynomial or the like is prepared in advance. An appropriate range is selected as the use data range in order to improve fitting accuracy. For example, the measurer can improve the accuracy of fitting by excluding a frame image indicating a remarkable sample damage caused by electron beam irradiation from the use data range among the acquired frame images.

The image processing unit 113 performs the following processing on frame images designated as the use data range among the frame images transmitted from the image forming unit 112. First, an image brightness value of a pixel of interest (x, y) of each frame image is acquired. Here, the image brightness value of the pixel of interest (x, y) is calculated as an average value of brightness values of N pixels in the vicinity (S13). The N pixels in the vicinity refers to pixels present within N pixels from the pixel of interest (x, y). N can take a value of 0 or more. In the case of N=0, the brightness value of the pixel of interest (one pixel) is 0. In the case of N=1, the brightness value is an average value of brightness values of a total of five pixels including the pixel of interest and pixels on upper, lower, left, and right sides of the pixel of interest. When N is too small, the brightness value is likely to be affected by noises included in a frame image, and when N is too large, a change of the image brightness value in the integration direction is less likely to appear, so that N is set to an appropriate value. When a frame image is translated due to drift, an image brightness value may be acquired after performing drift correction.

Subsequently, a brightness value change curve is obtained by using a designated model to fit a change of an image brightness value of the pixel of interest in the integration direction (S14). For example, when a linear expression model is designated, the brightness value change curve (straight line) is calculated by fitting to the linear expression model using a least squares method.

Subsequently, it is determined whether the brightness value change curve fits a frame image (S15). Based on a fitting result, an evaluation value is calculated for how much the brightness value change curve fits an image brightness value of the frame image. The degree of fitting can be quantitatively calculated using, for example, a coefficient of determination.

When a frame image includes M pixels, steps S13 to S15 are performed for each of the M pixels, and a brightness value change curve is calculated for all of the pixels constituting the frame image.

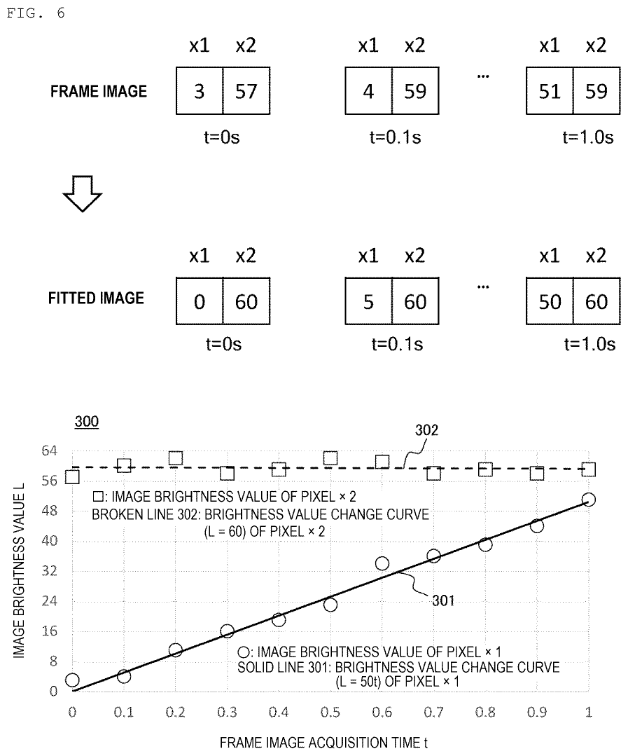

An example of calculating the brightness value change curve will be described with reference to FIG. 6 by taking an image including two pixels as an example. In a graph 300, a horizontal axis represents a frame image acquisition time t, and a vertical axis represents an image brightness value L. The integration direction is time, and 11 frame images are acquired every 0.1 s. In the graph 300, an image brightness value of a pixel x1 is indicated by a circle, and an image brightness value of a pixel x2 is indicated by a square. In FIG. 6, frame images at times 0 s, 0.1 s, and 1.0 s are schematically illustrated by image brightness values for each pixel. Frame images ({x1}, {x2}) at times 0 s, 0.1 s, and 1.0 s are (3, 57), (4, 59), and (51, 59), respectively. Here, {x1} represents the image brightness value of the pixel x1, and {x2} represents the image brightness value of the pixel x2.

A brightness value change curve (L=50 t) obtained by fitting the image brightness value {x1} of the pixel x1 with a linear expression of a time t is indicated by a solid line 301, and a brightness value change curve (L=60) obtained by fitting the image brightness value {x2} of the pixel x2 with a linear expression of a time t is indicated by a broken line 302.

When the fitting of the image brightness value is performed for each pixel, a large amount of calculation time is required. Therefore, when fitting according to the least squares method is performed, fitting using a matrix may be performed. When the fitting according to the least squares method of a polynomial is performed, the problem of obtaining an inverse matrix can be solved. Since a parameter (time in this case) in the integration direction is common to all pixels, the inverse matrix to be obtained is common to all pixels. Therefore, once the inverse matrix is calculated, only the product of the matrices is calculated later, so that the brightness value change curve for each pixel can be calculated in a short time.

Returning to description of the flowchart in FIG. 3 again. The image processing unit 113 generates a fitted image using the obtained brightness value change curve (S03). FIG. 6 illustrates a process of generating the fitted image using the brightness value change curve. In this case, since the fitting is performed with respect to the time t which is the integration direction, the fitted image ({x1}, {x2}) is (50 t, 60) using the brightness value change curve. Therefore, fitted images ({x1}, {x2}) at times 0 s, 0.1 s, and 1.0 s are (0, 60), (5, 60), and (50, 60), respectively.

As described above, by reflecting a global change of image brightness values on the brightness value change curve, it is possible to reduce an error of the image brightness value caused by noises and obtain a fitted image with a high SNR. The image processing unit 113 transmits a fitting result and a fitted image calculated by the above procedure to the control device 115.

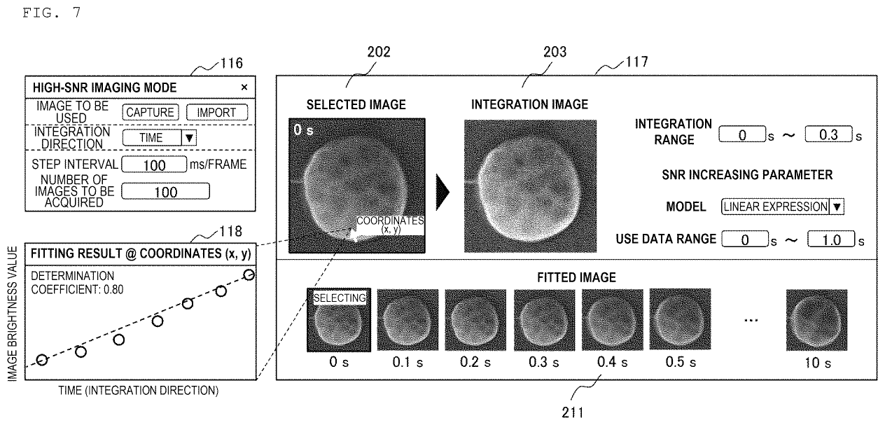

The control device 115 displays the received fitting result and fitted image on the GUI (S04). FIG. 7 illustrates a state of the GUI at this time. In a fitted image display region 211 of the window 117, fitted images generated using an SNR increasing parameter are displayed in the integration direction, in this case, according to time. That is, the frame images displayed in FIG. 5 are replaced with the fitted images with a high SNR. A fitted image selected by the measurer in the fitted image display region 211 is enlarged and displayed in the selected image display region 202. When an integration range is designated, an image obtained by integrating fitted images in the designated range (0 s to 0.3 s in the example in FIG. 7) is displayed in the integration image display region 203 (S05).

When the measurer selects any one pixel of a fitted image displayed in the selected image display region 202, the control device 115 displays a fitting result in the selected pixel in the window 118. The measurer determines a degree of the fitting result with reference to the brightness value change curve and a coefficient of determination (S06).

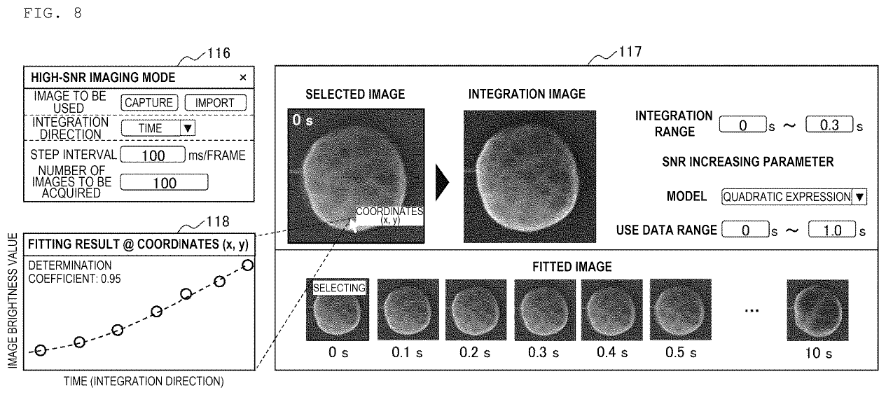

When the brightness value change is not sufficiently expressed in a selected model or when the measurer determines that overfitting or overlearning is performed, the measurer can update the SNR increasing parameter (S07). FIG. 8 illustrates a state of the GUI at this time. FIG. 8 illustrates an example in which a model is updated from a linear expression to a quadratic expression in the SNR increasing parameter. When the SNR increasing parameter is updated, the control device 115 transmits the updated parameter to the image processing unit 113, and again the image processing unit 113 calculates the brightness value change curve, calculates the coefficient of determination (evaluation value), and generates a fitted image based on the transmitted SNR increasing parameter, and transmits a result to the control device 115. The control device 115 updates display contents of the GUI so as to reflect the transmitted fitting result.

As described above, the measurer repeatedly performs an operation of updating the SNR increasing parameter and the integration range while checking a fitting result until an appropriate fitted image and an appropriate integration image are obtained.

In the present embodiment, it is possible to capture an SEM image at a high SNR in which an over-time change is captured, and since the process of increasing the SNR is visualized, it is possible to obtain a sense of satisfaction with appropriateness of increasing the SNR. In addition, since a fitted image is generated using a continuous brightness value change curve, it is possible to obtain a fitted image with a high SNR in which a change between frame images is complemented.

### Embodiment 2

Although an example is described in Embodiment 1 in which the integration direction is set as time and frame images are acquired over time, for example, an observation condition such as an acceleration voltage can also be selected as the integration direction. In Embodiment 2, an acceleration voltage, which is one observation condition, is selected as the integration direction. The configuration of the charged particle beam device 1 is similar to that in Embodiment 1. Differences from Embodiment 1 will be mainly described, and description overlapping with Embodiment 1 will be omitted.

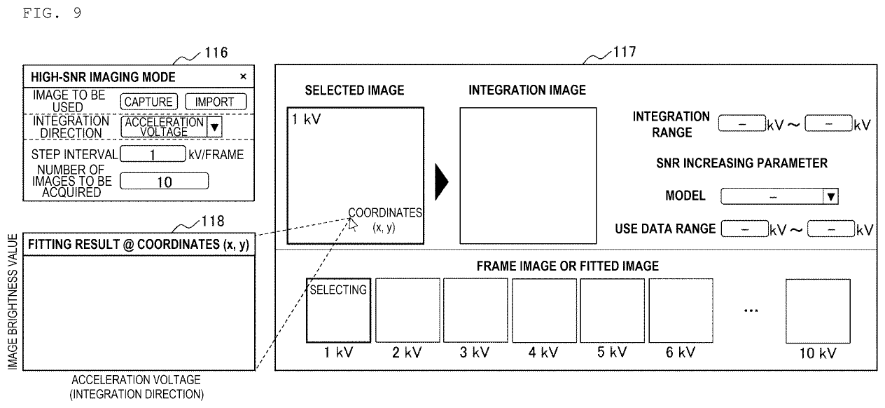

FIG. 9 illustrates a GUI displayed on the display device provided in the control device 115 in the Embodiment 2. The GUI includes windows the same as those in Embodiment 1.

A flowchart in Embodiment 2 is the same as that in FIG. 3 described in Embodiment 1. First, a plurality of frame images necessary for high-SNR imaging are acquired. In the present embodiment, parameters related to a high SNR are also prepared in a similar manner to Embodiment 1 as illustrated in FIG. 9. The window 116 is a window for a measurer to input a parameter related to high-SNR imaging, and an acceleration voltage is selected as the “integration direction”. Since the integration direction is the acceleration voltage, the step interval is also defined as a change amount of the acceleration voltage. In the example in FIG. 9, since the step interval is 1 kV per one frame and the number of images to be acquired is 10, it is set to acquire 10 frame images while changing the acceleration voltage by 1 kV. Accordingly, in step S01 (see FIG. 3), for example, continuous imaging of frame images at acceleration voltages of 1 kV to 10 kV is performed at an interval of 1 kV.

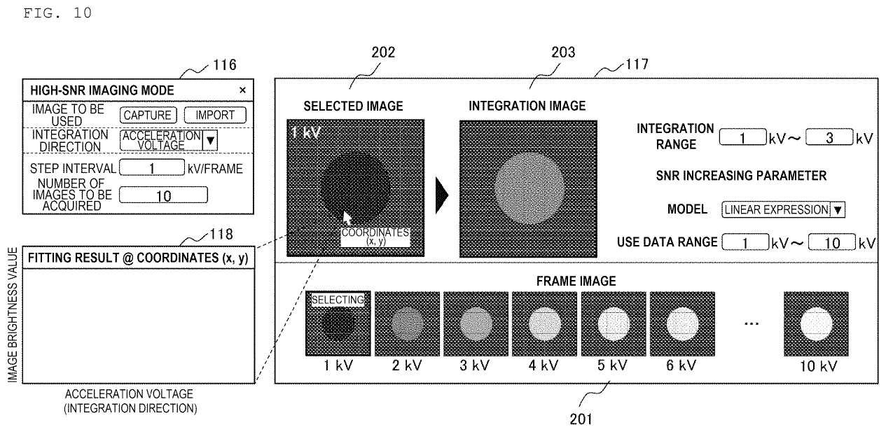

Similar to Embodiment 1, a brightness value change curve is obtained by modeling a change of a brightness value in the integration direction using captured frame images. FIG. 10 illustrates a state of the GUI at this time.

A measurer selects a model to be fitted and a use data range with reference to the frame images displayed in the frame image display region 201 of the GUI illustrated in FIG. 10 (S12, see FIG. 4). The unit of a parameter set in the window 117 is changed to the unit of the acceleration voltage according to the selection of the acceleration voltage as the integration direction.

The image processing unit 113 obtains a brightness value change curve by using the designated model to fit a change of image brightness values of pixels in the integration direction, that is, according to the acceleration voltage (S14). For example, when a linear expression model is designated, the brightness value change curve (straight line) is calculated by fitting to the linear expression model using a least squares method. Calculation of the brightness value change curve and calculation of an evaluation value of a fitting degree of the brightness value change curve are performed for all pixels constituting a frame image, and a fitted image is generated using the brightness value change curve (S03, see FIG. 3).

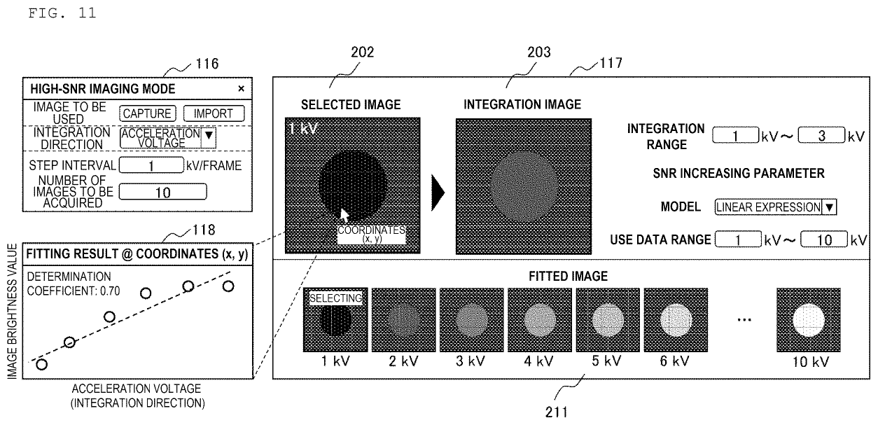

The control device 115 displays the received fitting result and fitted image on the GUI (S04). FIG. 11 illustrates a state of the GUI at this time. When an integration range is designated, an image obtained by integrating the fitted images in the designated range (1 kV to 3 kV in the example in FIG. 11) is displayed in the integration image display region 203 (S05). A fitting result is displayed in the window 118 in a similar manner to Embodiment 1.

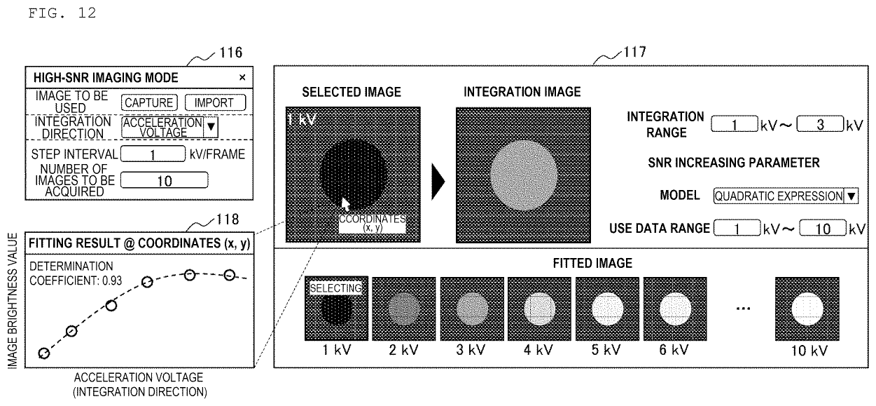

When the brightness value change is not sufficiently expressed in a selected model or when the measurer determines that overfitting or overlearning is performed, the measurer can update the SNR increasing parameter (S07). FIG. 12 illustrates a state of the GUI at this time. FIG. 12 is an example in which the model is updated from a linear expression to a quadratic expression in the SNR increasing parameter.

As described above, the measurer repeatedly performs an operation of updating the SNR increasing parameter and the integration range while checking a fitting result until an appropriate fitted image and an appropriate integration image are obtained.

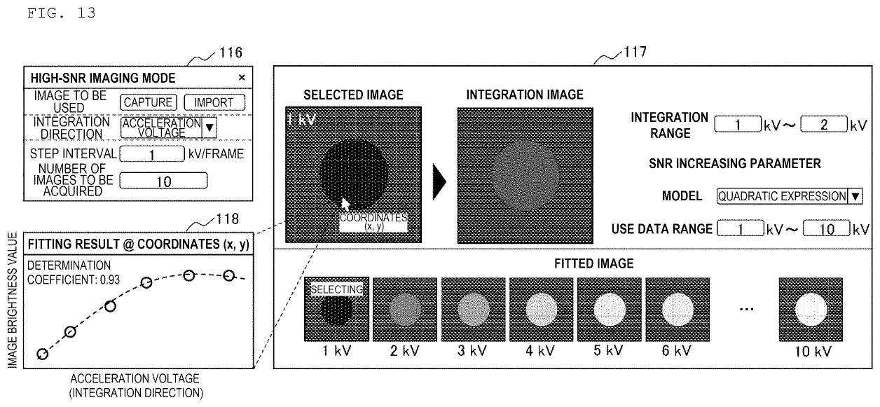

In addition, even when a step interval is not fine, it is possible to acquire an image with a high SNR under a desired observation condition. In an example according to Embodiment 2, images are acquired at a step interval of 1 kV, and, for example, a frame image at an acceleration voltage of 1.5 kV is not acquired. However, in the invention, since a global change in brightness values is fitted by a curve, as illustrated in FIG. 13, by setting the integration range to 1 kV to 2 kV, it is possible to acquire an image (fitted image) with a high SNR under an observation condition (1.5 kV) with which a frame image was not acquired, by performing interpolation between the image brightness value of the fitted image at the acceleration voltage of 1 kV and the image brightness value of the fitted image at the acceleration voltage of 2 kV.

### Embodiment 3

In Embodiment 3, an example of classifying regions in an image using a model will be described. The configuration of the charged particle beam device is the same as that in Embodiment 1, and an example in which time is selected as the integration direction will be described. Differences from Embodiment 1 will be mainly described, and description overlapping with Embodiment 1 will be omitted.

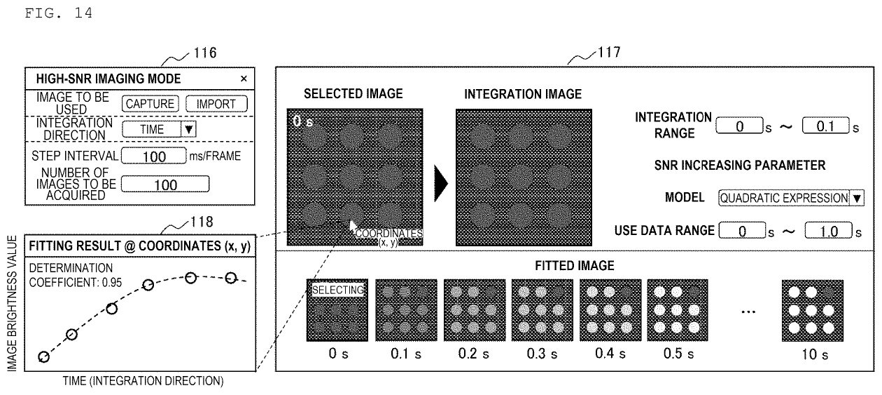

In Embodiment 3, a brightness value change curve is calculated by fitting to a model as illustrated in FIG. 14 by the same procedure as in Embodiment 1. It is assumed that a sample observed in FIG. 14 has nine circular regions in which image brightness values gradually increase corresponding to a time change due to charging by electron beam irradiation. These circular regions are referred to as regions 1, 2 . . . 9 from left to right and from top to bottom. The nine regions are classified into a normal region and an abnormal region using a coefficient of determination indicating a degree of fitting of the brightness value change curve or fitting of an image brightness value to the brightness value change curve.

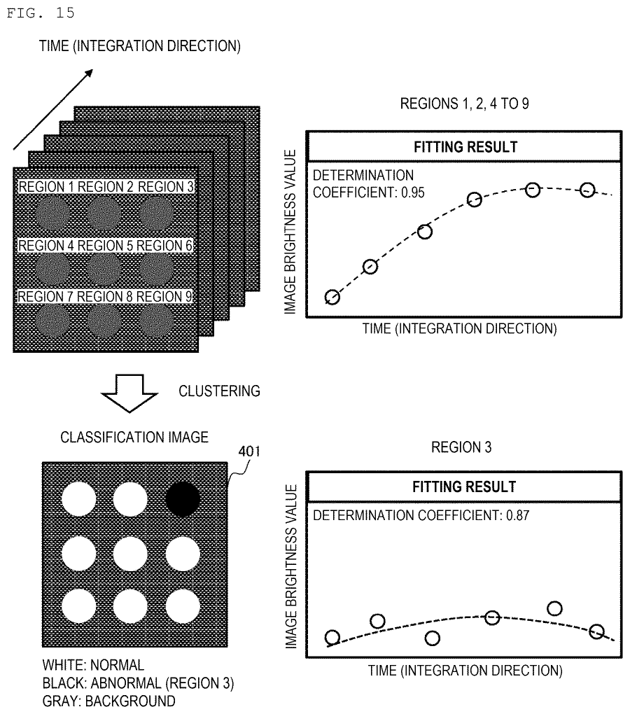

First, a classification method using a coefficient of determination will be described with reference to FIG. 15. Since the brightness value change curve and the coefficient of determination are calculated for each pixel (S14, S15, see FIG. 4), the coefficient of determination of each pixel is classified or clustered according to a threshold. For example, in the case of a normal region (for example, a region is normally insulated) and a change in the integration direction of image brightness values of pixels included in the region can be well expressed by a quadratic expression model, a threshold of a coefficient of determination can be determined to be, for example, 0.9. In the abnormal region, image brightness values of a frame image are poorly fitted to the brightness value change curve, and in the normal region, image brightness values of a frame image are well fitted to the brightness value change curve, so that a region is determined to be normal or abnormal according to a threshold. In the example in FIG. 15, it can be determined that the regions 1, 2, 4 to 9 in which the coefficient of determination exceeds 0.9 are normal, and the region 3 in which the coefficient of determination does not reach 0.9 is abnormal.

Further, since a region can be classified into only two types in the classification according to the threshold, a clustering method such as the k-MEANS method may be used when a region is classified into three or more types in consideration of a background region. In addition, at the time of classification, statistics such as an average value of brightness values of pixels constituting a clustered region may also be classified.

Next, a classification method using the brightness value change curve will be described. In this case, classification is performed by focusing on a shape of the brightness value change curve. For example, a value of slope or intercept of a curve, the number or a position of an extreme value, a coefficient of a polynomial, and the like can be considered. In addition, it is also possible to perform clustering by regarding time-series data of brightness values represented by a curve as vectors. When the shape of the brightness value change curve is used, there is an advantage in that, in the case of a normal region, it is possible to classify which model can better express a change of image brightness values of a frame image in the integration direction even if the change is not known. Similar to the case of coefficient of determination, statistics such as an average value of brightness values of pixels constituting a clustered region may also be classified.

The image processing unit 113 performs classification according to any one of the methods described above, transmits a classification result to the control device 115, and displays the classification result on the GUI. For example, a classification image 401 illustrated in FIG. 15 is displayed. In the classification image 401, frame images or fitted images in three regions of normal, abnormal, and background are classified, and the region 3 is indicated as an abnormal region.

The invention is not limited to the embodiments described above, and includes various modifications. For example, the embodiments described above have been described for easy understanding of the invention, and the invention is not necessarily limited to those including all the configurations described above. A part of a configuration of a certain embodiment can be replaced with a configuration of another embodiment, and a configuration of another embodiment can be added to a configuration of a certain embodiment. In addition, another configuration can be added to a part of a configuration of each embodiment, and a part of a configuration of each embodiment can be deleted or replaced with another configuration. A part or all of the above configurations, functions, processing units, processing means, and the like may be implemented by hardware, for example, by designing an integrated circuit.

### REFERENCE SIGNS LIST

101: electron gun
102: condenser lens
103: diaphragm
104: deflection coil
105: stigma coil
106: objective lens
107: sample
108: sample stage
109: detector
110: electron beam
111: secondary electron
112: image forming unit
113: image processing unit
114: device control unit
115: control device
116, 117, 118: window
120: computer
121: processor (CPU)
122: memory
123: auxiliary storage device
124: communication interface
125: bus
201: frame image display region
202: selected image display region
203: integration image display region
211: fitted image display region
300: graph
301, 302: brightness value change curve
401: classification image

1. A charged particle beam device comprising:
a charged particle optical system configured to irradiate a sample with a charged particle beam;
a detector configured to detect particles or electromagnetic waves generated by irradiating the sample with the charged particle beam;
an image forming unit configured to form a frame image that is a charged particle beam image based on a detection signal from the detector; and
an image processing unit configured to perform image processing on the frame image, wherein
the image forming unit acquires a plurality of the frame images in an integration direction, and
the image processing unit obtains a brightness value change curve by using a designated model to fit a change of an image brightness value of a pixel in the integration direction for each pixel constituting the frame image, and generates a fitted image in which a brightness value of the pixel is a value based on the brightness value change curve.

2. The charged particle beam device according to claim 1, wherein
the image processing unit calculates an evaluation value indicating a degree of fitting the image brightness value of the frame image to the brightness value change curve.

3. The charged particle beam device according to claim 2, wherein
the image processing unit classifies the frame image or the fitted image into a plurality of regions based on the brightness value change curve or the evaluation value of the brightness value change curve.

4. The charged particle beam device according to claim 1, wherein
the image processing unit integrates a plurality of the fitted images to generate an integration image.

5. The charged particle beam device according to claim 1, wherein
the image processing unit sets the image brightness value of the pixel of the frame image to an average value of brightness values of N pixels (N is an integer of 0 or more) in the vicinity of a pixel of interest.

6. The charged particle beam device according to claim 1, further comprising:
a control device, wherein
the control device is configured to select the integration direction in which the frame image is acquired, and
a time and an observation condition of the sample are included as selectable integration directions.

7. The charged particle beam device according to claim 6, wherein
the control device is configured to select a model for obtaining the brightness value change curve.

8. An image processing method for improving, using a computer, an SNR of a frame image which is a charged particle beam image formed by a detector detecting particles or electromagnetic waves generated by irradiating a sample with a charged particle beam, the image processing method comprising:
acquiring a plurality of the frame images in an integration direction;
obtaining a brightness value change curve by using a designated model to fit a change of an image brightness value of a pixel in the integration direction for each pixel constituting the frame image;
generating a fitted image in which the brightness value of the pixel is a value based on the brightness value change curve; and
outputting the fitted image or an integration image obtained by integrating a plurality of the fitted images.

9. The image processing method according to claim 8, wherein
an evaluation value indicating a degree of fitting the image brightness value of the frame image to the brightness value change curve is calculated.

10. The image processing method according to claim 9, wherein
the frame image or the fitted image is classified into a plurality of regions based on the brightness value change curve or the evaluation value of the brightness value change curve.

11. The image processing method according to claim 8, wherein
the image brightness value of the pixel of the frame image is set to an average value of brightness values of N pixels (N is an integer of 0 or more) in the vicinity of a pixel of interest.

12. The image processing method according to claim 8, wherein
the integration direction in which the frame image is acquired is selected from either a time or an observation condition of the sample.

13. The image processing method according to claim 9, wherein
the model for obtaining the brightness value change curve is updated based on the evaluation value of the brightness value change curve.

14. An image processing program for causing a computer to perform image processing for improving an SNR of a frame image which is a charged particle beam image formed by a detector detecting particles or electromagnetic waves generated by irradiating a sample with a charged particle beam, the image processing program causing the computer to execute:
a first procedure of acquiring a plurality of the frame images in an integration direction;
a second procedure of obtaining a brightness value change curve by using a designated model to fit a change of an image brightness value of a pixel in the integration direction for each pixel constituting the frame image;
a third procedure of generating a fitted image in which the brightness value of the pixel is a value based on the brightness value change curve; and
a fourth procedure of outputting the fitted image or an integration image obtained by integrating a plurality of the fitted images.

15. The image processing program according to claim 14, wherein
in the second procedure, the image brightness value of the pixel of the frame image is set to an average value of brightness values of N pixels (N is an integer of 0 or more) in the vicinity of a pixel of interest.
